(19) United States
(12) Patent Application Publication
(10) Pub. No.: US 2019/0228534 A1
(43) Pub. Date: Jul. 25, 2019

(54) IMAGE PICKUP DEVICE, IMAGE PICKUP SYSTEM, AND MOVING APPARATUS

(71) Applicant: CANON KABUSHIKI KAISHA, Tokyo (JP)

(72) Inventors: Taro Kato, Tokyo (JP); Hidekazu Takahashi, Zama-shi (JP)

(21) Appl. No.: 16/249,322

(22) Filed: Jan. 16, 2019

(30) Foreign Application Priority Data
Jan. 23, 2018 (JP) 2018-008967

(51) Int. Cl. G06T 7/50; H01L 27/146; H04N 5/369; H04N 5/3745; H04N 5/357

(52) U.S. Cl. CPC G06T 7/50; H01L 27/14645; H04N 5/36961; G06T 2207/30252; H04N 5/357; G06T 2207/10028; H04N 5/3745

(57) ABSTRACT

An image pickup device includes a plurality of pixels which are two-dimensionally arranged on a substrate. At least one of the plurality of pixels includes a first photoelectric conversion unit and a second photoelectric conversion unit arranged side by side in a first direction; and a third photoelectric conversion unit arranged between the first photoelectric conversion unit and the second photoelectric conversion unit in the first direction. The first photoelectric conversion unit, the second photoelectric conversion unit, and the third photoelectric conversion unit respectively have shapes that are not point symmetric in a plan view.

### BACKGROUND OF THE INVENTION

### Field of the Invention

The present invention relates to an image pickup device, an image pickup system, and a moving apparatus.

### Description of the Related Art

Conventionally, as an image pickup device, a configuration provided with pixels each including a light receiving unit in which a photoelectric conversion layer is provided on a substrate is known. In addition, image pickup systems equipped with an automatic focusing (AF) function which automatically adjusts focusing during photography are being widely used. Japanese Patent Application Laid-open No. 2016-33981 describes a photoelectric conversion unit having an organic or inorganic photoelectric conversion film and an upper electrode and a lower electrode provided so as to sandwich the photoelectric conversion film. In addition, Japanese Patent Application Laid-open No. 2016-33981 describes an image pickup system which performs focus detection by a phase difference system by dividing a lower electrode into a plurality of parts to provide a plurality of photoelectric conversion units. The phase difference system obtains a defocus amount and a distance to an object according to the principle of triangulation based on a phase difference of a parallax image created by a luminous flux having passed through different regions (pupil regions) on a pupil of a lens.

### SUMMARY OF THE INVENTION

In vehicle-mounted ranging cameras also capable of acquiring picked-up images, application of an image pickup device also capable of realizing high ranging accuracy is desired for the purpose of acquiring information for autonomous movement.

In addition, a catadioptric system which combines a lens with a mirror is conceivably usable as an image pickup optical system for the purpose of downsizing a ranging camera. However, when the catadioptric system creates an asymmetric optical system, since images are asymmetrically distorted, there is a concern that ranging accuracy may decline.

The present invention has been made in consideration of the circumstances described above and an object thereof is to suppress image distortion due to an image pickup optical system and to improve ranging accuracy.

A first aspect of the present invention provides an image pickup device in which a plurality of pixels are two-dimensionally arranged on a substrate, wherein at least one of the plurality of pixels includes: a first photoelectric conversion unit and a second photoelectric conversion unit arranged side by side in a first direction; and a third photoelectric conversion unit arranged between the first photoelectric conversion unit and the second photoelectric conversion unit in the first direction, and the first photoelectric conversion unit, the second photoelectric conversion unit, and the third photoelectric conversion unit respectively have shapes that are not point symmetric in a plan view.

A second aspect of the present invention provides an image pickup device in which a plurality of pixels are two-dimensionally arranged on a substrate, wherein at least one of the plurality of pixels includes: a first photoelectric conversion unit and a second photoelectric conversion unit arranged side by side in a first direction; and a third photoelectric conversion unit arranged between the first photoelectric conversion unit and the second photoelectric conversion unit in the first direction, and a position of a center of gravity of the first photoelectric conversion unit and a position of a center of gravity of the second photoelectric conversion unit are displaced toward a same side from a center of the pixel in a second direction that is perpendicular to the first direction in a plane parallel to a surface of the substrate, and a position of a center of gravity of the third photoelectric conversion unit is displaced toward an opposite side to the position of the center of gravity of the first photoelectric conversion unit and the position of the center of gravity of the second photoelectric conversion from the center of the pixel in the second direction.

According to the present invention, image distortion due to an image pickup optical system can be suppressed and ranging accuracy can be improved.

Further features of the present invention will become apparent from the following description of exemplary embodiments with reference to the attached drawings.

### BRIEF DESCRIPTION OF THE DRAWINGS

FIG. 1 is a schematic view showing a configuration of an image pickup system according to a first embodiment;

FIG. 2 is a block diagram showing an image pickup device having a ranging pixel and an image pickup pixel according to the first embodiment;

FIGS. 3A and 3B are diagrams for explaining a pixel according to the first embodiment;

FIGS. 4A and 4B are diagrams for explaining a pixel according to a comparative example;

FIGS. 5A and 5B are diagrams for explaining a relationship among a pixel, an object, and an exit pupil according to the comparative example;

FIGS. 6A and 6B are diagrams for explaining a relationship among a pixel, an object, and an exit pupil according to the first embodiment;

FIGS. 7A and 7B are diagrams for explaining that a size of a photoelectric conversion unit changes in accordance with voltage between an electrode and an upper electrode;

FIGS. 8A and 8B are diagrams for explaining a pixel according to a second embodiment;

FIGS. 9A and 9B are diagrams for explaining a relationship between a pixel, an object, and an exit pupil according to the second embodiment;

FIGS. 10A and 10B are diagrams for explaining a mode in which four or more electrodes are arranged in a pixel;

FIGS. 11A and 11B are diagrams for explaining a pixel according to a third embodiment; and

FIGS. 12A and 12B are diagrams showing configurations of an image pickup system and a moving apparatus according to a fourth embodiment.

### DESCRIPTION OF THE EMBODIMENTS

Hereinafter, an example of a specific embodiment of an image pickup device according to the present invention will be described with reference to the drawings. An image pickup device is a semiconductor device having a plurality of pixels which convert light into an electrical signal and is also referred to as a solid-state image pickup element or an image sensor. Image pickup devices include a CCD image sensor and a CMOS image sensor. It is to be understood that commonly known or publicly known techniques in relevant technical fields can be applied to portions not specifically illustrated or described in the present embodiment. It is also to be understood that materials, shapes, relative arrangements, and the like of components described in the present embodiment are intended to be changed as deemed appropriate in accordance with configurations and various conditions of apparatuses to which the invention is to be applied and are not intended to limit the scope of the invention to the practical modes described below.

### First Embodiment

### Overall Configuration of Image Pickup System

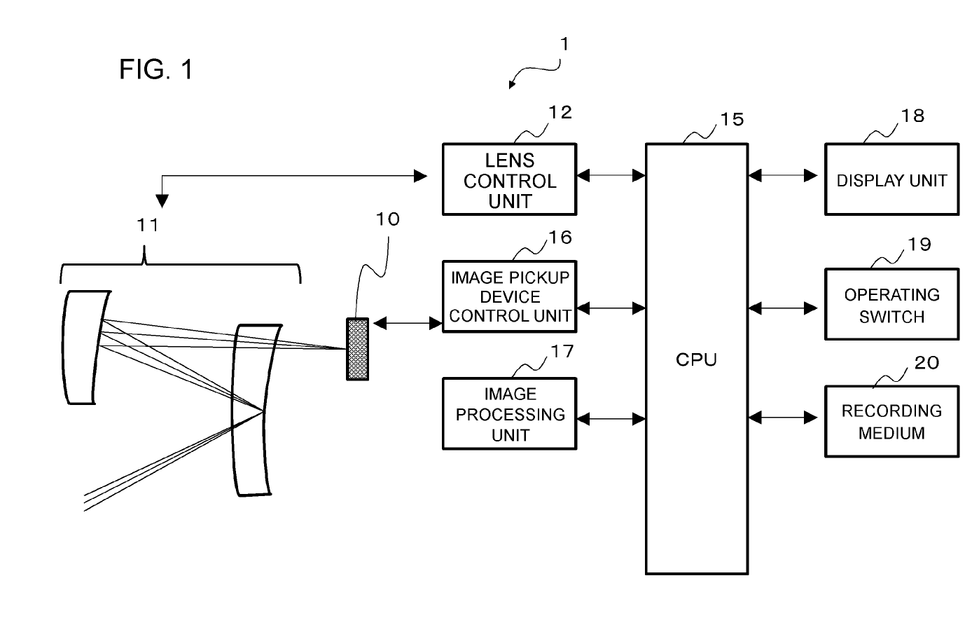

FIG. 1 is a configuration diagram showing a configuration of an image pickup system 1.

As shown in FIG. 1, the image pickup system 1 is provided with an image pickup device 10, an image pickup optical system 11, a lens control unit 12, a CPU 15, an image pickup device control unit 16, an image processing unit 17, a display unit 18, an operating switch 19, and a recording medium 20.

The image pickup optical system 11 is an optical system for forming an optical image of an object and, in the present embodiment, indicates an asymmetric catadioptric system combining a lens and a mirror. Using an asymmetric catadioptric system enables, for example, a vehicle-mounted camera to be downsized. The lens and the mirror are held so as to be movable back and forth in an optical axis direction, and a variable magnification function (a zoom function) and a focusing function are realized by interlocked operations of the lens and the mirror. The image pickup optical system 11 may be integrated with the image pickup system or may be an image pickup lens that is mountable to the image pickup system.

The image pickup device 10 is disposed in an image space of the image pickup optical system 11 so that an image pickup plane of the image pickup device 10 is positioned in the image space. As will be described later, the image pickup device 10 is configured so as to include a CMOS sensor (a pixel region 121) and peripheral circuits (a peripheral circuit region) thereof. In the image pickup device 10, a plurality of pixels with a photoelectric conversion unit are two-dimensionally arranged, and a color filter is disposed relative to the pixels to constitute a two-dimensional single-board color sensor. The image pickup device 10 photoelectrically converts an object image formed by the image pickup optical system 11 and outputs the photoelectrically converted object image as an image signal or a focus detection signal.

The lens control unit 12 is for performing variable magnification operations and focusing by controlling the image pickup optical system 11 and is constituted by circuits and processing devices configured so as to realize such functions.

The CPU 15 is a control device inside the camera which performs various control of a camera main body, and includes a calculating unit, a ROM, a RAM, an A/D converter, a D/A converter, a communication interface circuit, and the like. The CPU 15 controls operations of various parts inside the camera in accordance with a computer program stored in the ROM or the like and executes a series of photographic operations such as measurement of a distance to an object, AF including detection of a focus state (focus detection) of the image pickup optical system 11, image pickup, image processing, and recording. The CPU 15 is also a signal processing unit.

The image pickup device control unit 16 is for controlling operations of the image pickup device 10 as well as subjecting a pixel signal (an image pickup signal) output from the image pickup device 10 to A/D conversion and transmitting the pixel signal subjected to A/D conversion to the CPU 15, and is constituted by circuits and control devices configured so as to realize such functions. The A/D conversion function may be provided in the image pickup device 10 instead.

The image processing unit 17 is for performing image processing such as y conversion and color interpolation on the signal subjected to A/D conversion and generating an image signal and is constituted by circuits and control devices configured so as to realize such functions.

The display unit 18 is a display device such as a liquid crystal display device (LCD) and displays information related to a photography mode of the camera, a preview image prior to photography, a confirmation image after photography, a focusing state upon focus detection, and the like. The operating switch 19 is constituted by a power supply switch, a release (photography trigger) switch, a zoom operation switch, a photography mode selection switch, and the like. The recording medium 20 is for recording photographed images and the like and may be built into the image pickup system or may be a mountable and detachable recording medium such as a memory card.

Overall Configuration of Image Pickup Device

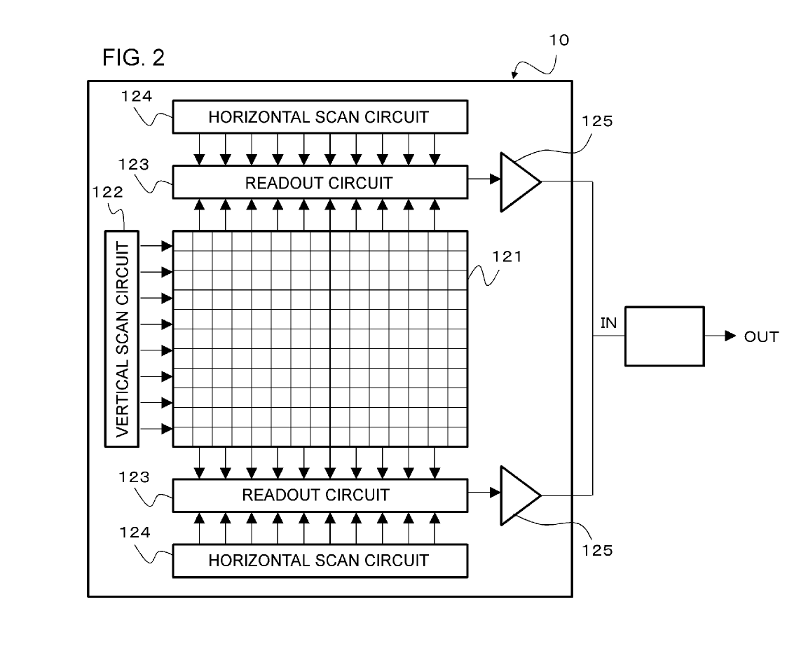

FIG. 2 is a block diagram showing the image pickup device 10 having a ranging pixel and an image pickup pixel according to the present embodiment.

The image pickup device 10 is provided with a pixel region 121, a vertical scan circuit 122, two readout circuits 123, two horizontal scan circuits 124, and two output amplifiers 125. The vertical scan circuit 122, the two readout circuits 123, the two horizontal scan circuits 124, and the two output amplifiers 125 are provided in the peripheral circuit region which is a region other than the pixel region 121.

In the pixel region 121, a large number of ranging pixels and image pickup pixels are arranged in a two-dimensional pattern. The readout circuits 123 are provided with, for example, a column amplifier, a correlated double sampling (CDS) circuit, an adder circuit, and the like and subject a signal read via a vertical signal line from a pixel in a row selected by the vertical scan circuit 122 to amplification, addition, and the like. The horizontal scan circuits 124 generate a signal for sequentially reading signals based on pixel signals from the readout circuits 123. The output amplifiers 125 amplify and output signals of a column selected by the horizontal scan circuits 124.

It should be noted that, while a configuration in which an electron is used as a signal charge will be exemplified in the description below, a hole can also be used as a signal charge.

In addition, the present embodiment will be described by plotting mutually perpendicular xy axes on a plane parallel to a surface of a substrate on which the pixels are arranged and plotting a z axis in a direction perpendicular to the substrate surface. Furthermore, a positive direction of the z axis may also be referred to as upward and a negative direction of the z axis may also be referred to as downward.

Element Configuration of Each Pixel

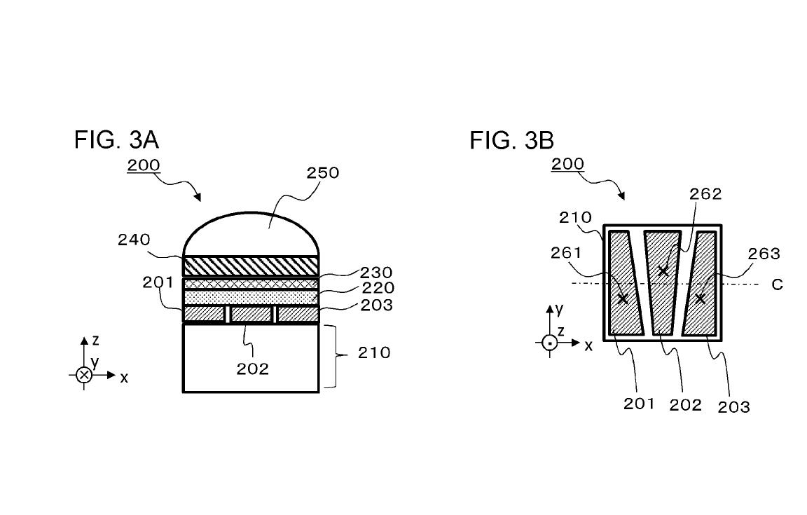

FIG. 3A is a sectional view schematically showing an xz plane of a pixel 200 according to the present embodiment.

In FIG. 3A, a member 210 schematically represents a portion in which a semiconductor substrate, a wiring layer, a readout circuit, and the like are arranged. An electrode 201 (a first pixel electrode), an electrode 202 (a third pixel electrode), and an electrode 203 (a second pixel electrode) which constitute a lower electrode are provided on the member 210.

A photoelectric conversion layer 220 is provided on the electrode 201, the electrode 202, and the electrode 203, and an upper electrode (a counter electrode) 230 is provided on the photoelectric conversion layer 220. A color filter 240 is provided on the upper electrode 230. A microlens 250 is provided above the color filter 240. A planarizing layer may be provided between the color filter 240 and the microlens 250.

In this case, respective regions corresponding to a shape of the electrode 201 in the photoelectric conversion layer 220 and the upper electrode 230 constitute a first photoelectric conversion unit together with the electrode 201. In addition, respective regions corresponding to a shape of the electrode 202 in the photoelectric conversion layer 220 and the upper electrode 230 constitute a third photoelectric conversion unit together with the electrode 202. Furthermore, respective regions corresponding to a shape of the electrode 203 in the photoelectric conversion layer 220 and the upper electrode 230 constitute a second photoelectric conversion unit together with the electrode 203. The first photoelectric conversion unit and the second photoelectric conversion unit are for detecting a phase difference.

The electrode 201, the electrode 202, and the electrode 203 are electrodes formed by a conductive member such as aluminum or copper. The electrode 201, the electrode 202, and the electrode 203 are for separating and collecting charges generated in respective regions of the photoelectric conversion layer 220. The photoelectric conversion layer 220 is constituted by a material that is an organic compound or an inorganic compound which generates a charge in accordance with a light intensity of incident light.

The upper electrode 230 is an electrode for applying voltage to the photoelectric conversion layer 220 to generate an electric field on the photoelectric conversion layer 220. Since the upper electrode 230 is provided on a side of a light incident surface with respect to the photoelectric conversion layer 220, the upper electrode 230 is constituted by a conductive material such as ITO (Indium Tin Oxide) which is transparent with respect to incident light.

The color filter 240 is a filter which transmits light of R (red), G (green), and B (blue) or light of C (cyan), M (magenta), and Y (yellow). In addition, the color filter 240 may be a white color filter. The microlens 250 is formed using a material such as resin.

FIG. 3B is a sectional view schematically showing a cross section obtaining by cutting the electrodes 201, 202, and 203 in the pixel 200 along an xy plane. In the following description, a view of the xy plane of a pixel from above as shown in FIG. 3B may also be referred to as a plan view.

The electrode 201 and the electrode 203 are arranged near both ends of the pixel 200 in an x direction (a first direction). In addition, the electrode 202 is arranged between the electrode 201 and the electrode 203.

The x direction in which the electrodes 201, 202, and 203 are aligned constitutes a phase difference detection direction. Distance measurement is performed based on signals obtained from the electrode 201 and the electrode 203. Acquisition of a picked-up image is performed based on only a signal obtained from the electrode 202 or a signal obtained by synthesizing signals from the electrodes 201, 202, and 203. For example, a region provided with one microlens can be defined as one pixel.

In the plan view shown in FIG. 3B, a direction perpendicular to the x direction is assumed to be a y direction (a second direction).

A feature of the present embodiment is that, in a plan view, a center of gravity position 261 of the electrode 201 and a center of gravity position 263 of the electrode 203 are displaced in a −y direction from a pixel center C. In addition, a center of gravity position 262 of the electrode 202 is displaced toward an opposite side in the y direction relative to the center of gravity position 261 and the center of gravity position 263 from the pixel center C or, in other words, in a +y direction.

Furthermore, shapes of the electrodes 201, 202, and 203 are respectively shapes which are not point symmetric (two-fold symmetric) and which differ from one another in a plan view.

Hereinafter, the pixel 200 according to the present embodiment will be described by comparing the pixel 200 with a pixel 1000 according to a comparative example.

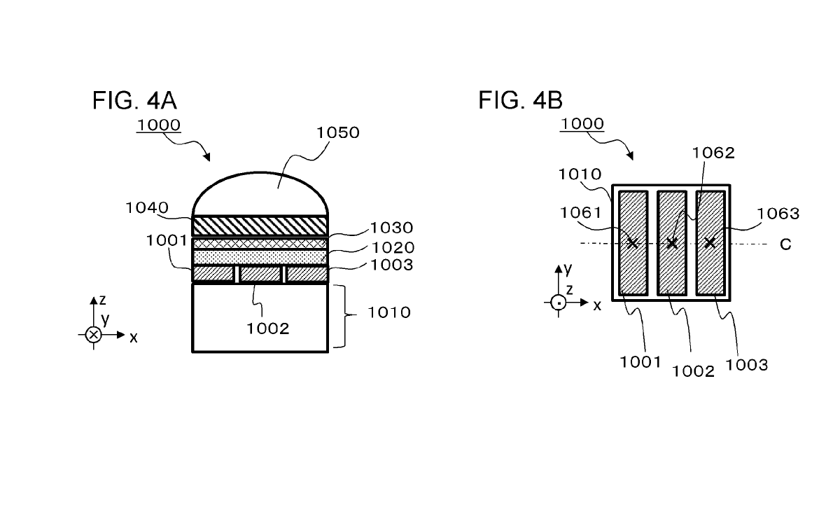

FIG. 4A is a sectional view schematically showing an xz plane of the pixel 1000 according to the comparative example. FIG. 4B is a sectional view schematically showing an xy plane of electrodes 1001, 1002, and 1003 of the pixel 1000 according to the comparative example.

A member 1010, the electrodes 1001, 1002, and 1003, an upper electrode 1030, and a photoelectric conversion layer 1020 shown in FIG. 4A correspond to the member 210, the electrodes 201, 202, and 203, the upper electrode 230, and the photoelectric conversion layer 220 shown in FIG. 3A. In addition, a color filter 1040 and a microlens 1050 shown in FIG. 4A correspond to the color filter 240 and the microlens 250 shown in FIG. 3A. In the photoelectric conversion layer 1020, regions corresponding to shapes of the electrodes 1001, 1002, and 1003 constitute divided photoelectric conversion units.

In the comparative example, as shown in FIG. 4B, a center of gravity position 1061 of the electrode 1001, a center of gravity position 1062 of the electrode 1002, and a center of gravity position 1063 of the electrode 1003 are same positions as a pixel center C in the y direction in a plan view. In addition, shapes of the electrodes 1001, 1002, and 1003 are respectively point symmetric shapes in a plan view.

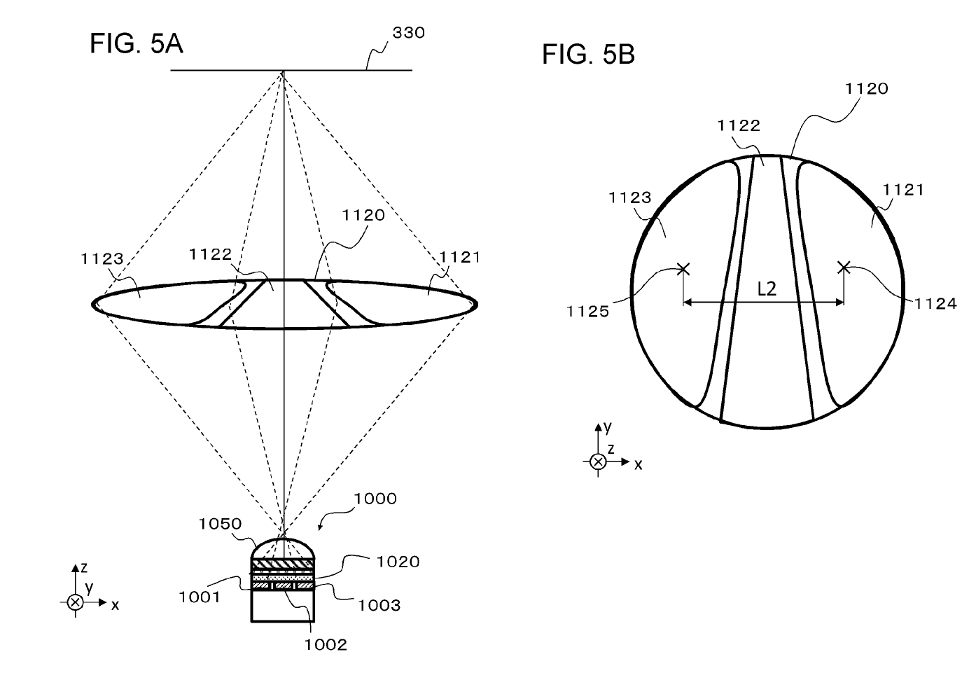

FIG. 5A is a diagram for explaining a relationship among the pixel 1000, an object 330, and an exit pupil 1120 according to the comparative example in the asymmetric image pickup optical system 11 shown in FIG. 1.

While an optical axis is folded in the image pickup optical system 11 shown in FIG. 1, the pixel 1000, the exit pupil 1120, and the object 330 are schematically shown arranged in one row in FIG. 5A for the sake of brevity. FIG. 5B is a diagram schematically showing an xy plane of the exit pupil 1120. In the diagram, the x direction is assumed to be a pupil-splitting direction, and respective regions of the split exit pupil 1120 are assumed to be pupil regions 1121, 1122, and 1123. The exit pupil 1120 and the photoelectric conversion layer 1020 have a conjugate relationship via the microlens 1050.

When light having passed through the pupil region 1121 is incident to the pixel 1000, a charge is generated in a portion positioned above the electrode 1001 in the photoelectric conversion layer 1020. In addition, when light having passed through the pupil region 1122 is incident to the pixel 1000, a charge is generated in a portion positioned above the electrode 1002 in the photoelectric conversion layer 1020. Furthermore, when light having passed through the pupil region 1123 is incident to the pixel 1000, a charge is generated in a portion positioned above the electrode 1003 in the photoelectric conversion layer 1020.

In the configuration of the comparative example shown in FIG. 5A, two pieces of parallax information are acquired from a signal charge collected by the electrode 1001 and a signal charge collected by the electrode 1003, thereby enabling distance measurement using the principle of triangulation. In addition, a picked-up image is acquired based on only a signal from the electrode 1002 or based on a signal obtained by synthesizing signals from the electrodes 1001, 1002, and 1003.

Images of the photoelectric conversion units (the electrodes 1001, 1002, and 1003) of the pixel 1000 projected on the exit pupil 1120 through the asymmetric image pickup optical system 11 take on asymmetric shapes as represented by the pupil regions 1121, 1122, and 1123 shown in FIG. 5B. In the present specification, an asymmetric shape refers to a shape that is not two-fold symmetric.

When the pupil regions 1121 and 1123 take on asymmetric distorted shapes, there is a concern that a distance L2 between a center of gravity position 1124 of the pupil region 1121 and a center of gravity position 1125 of the pupil region 1123 may become shorter and ranging accuracy may decline. In addition, since a picked-up image acquired based on a signal from the electrode 1002 is formed by light transmitted through the distorted pupil region 1122, there is a concern that the image may also be distorted.

In consideration thereof, in the present embodiment, image distortion due to the image pickup optical system 11 is suppressed by applying the pixel 200 in which photoelectric conversion units (the electrodes 201, 202, and 203) are given asymmetric shapes as shown in FIG. 3B to the image pickup system 1.

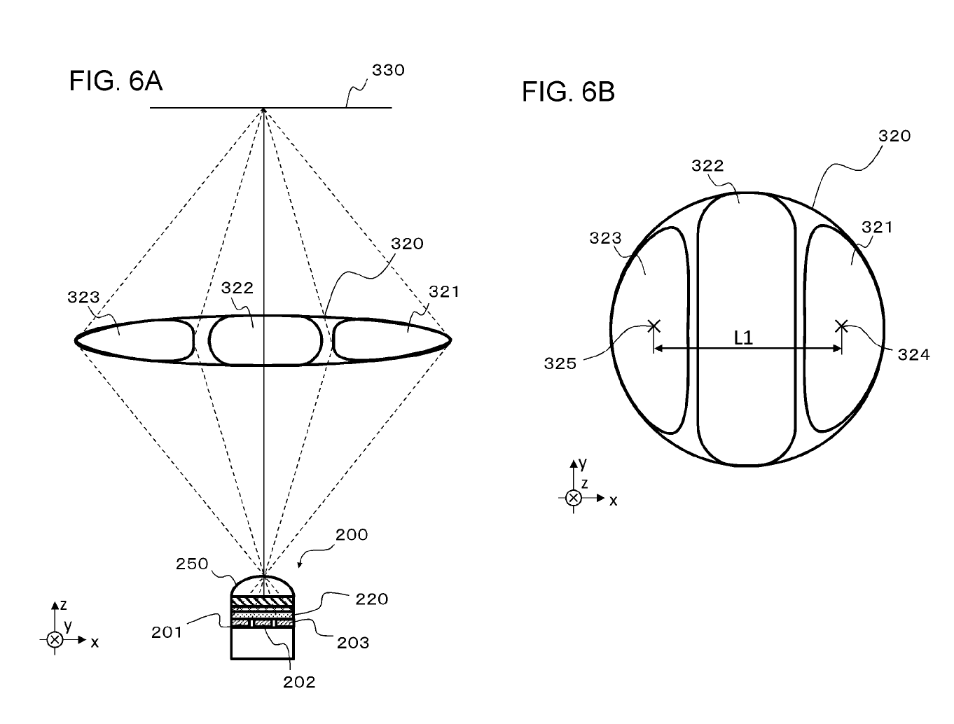

FIG. 6A is a diagram for explaining a relationship among the pixel 200, an exit pupil 320, and the object 330 according to present embodiment in the asymmetric image pickup optical system 11 shown in FIG. 1. While the optical axis is folded in the image pickup optical system 11 shown in FIG. 1, the pixel 200, the exit pupil 320, and the object 330 are schematically shown arranged in one row in FIG. 6A for the sake of brevity.

FIG. 6B is a diagram schematically showing an xy plane of the exit pupil 320. In the diagram, the x direction is assumed to be a pupil-splitting direction, and respective regions of the split exit pupil 320 are assumed to be pupil regions 321, 322, and 323. The exit pupil 320 and the photoelectric conversion layer 220 have a conjugate relationship via the microlens 250.

When light having passed through the pupil region 321 is incident to the pixel 200, a charge is generated in a portion positioned above the electrode 201 in the photoelectric conversion layer 220. In addition, when light having passed through the pupil region 322 is incident to the pixel 200, a charge is generated in a portion positioned above the electrode 202 in the photoelectric conversion layer 220. Furthermore, when light having passed through the pupil region 323 is incident to the pixel 200, a charge is generated in a portion positioned above the electrode 203 in the photoelectric conversion layer 220. In the configuration of the present embodiment shown in FIG. 6A, two pieces of parallax information are acquired from a signal charge collected by the electrode 201 and a signal charge collected by the electrode 203, thereby enabling distance measurement using the principle of triangulation. In addition, a picked-up image is acquired based on only a signal from the electrode 202 or based on a signal obtained by synthesizing signals from the electrodes 201, 202, and 203.

Even with the asymmetric image pickup optical system 11 as shown in FIG. 1, applying the pixel 200 according to the present embodiment causes the pupil regions 321, 322, and 323 shown in FIGS. 6A and 6B to take on point symmetric shapes.

Accordingly, a distance L1 between a center of gravity position 324 of the pupil region 321 and a center of gravity position 325 of the pupil region 323 can be kept longer than the distance L2 of the comparative example shown in FIG. 5B.

In addition, in the pixel 200 according to the present embodiment, since the electrodes 201 and 203 are arranged near the ends of the pixel 200, the pupil regions 321 and 323 shown in FIGS. 6A and 6B also end up being positioned near ends of the exit pupil 320. As a result, the distance L1 between the centers of gravity of the pupil regions 321 and 323 which correspond to each parallax becomes longer (parallax increases) and, in accordance with the principle of triangulation, accuracy of the distance can be further increased. In addition, a picked-up image formed by light transmitted through the pupil region 322 with a point symmetric shape can be acquired without distortion as compared to a picked-up image formed by light transmitted through the pupil region 1122 according to the comparative example.

In order to acquire a signal of light transmitted through the pupil regions 321 and 323 for ranging, an aperture of the image pickup optical system 11 must be set to maximum aperture. However, when using all of the beams of light respectively having passed through the pupil regions 321, 322, and 323 to acquire a picked-up image from a signal obtained by synthesizing signals from the electrodes 201, 202, and 203, there is a concern that a depth of field may become shallow.

In consideration thereof, when acquiring a picked-up image by setting the aperture of the image pickup optical system 11 to maximum aperture for the purpose of ranging, only the light transmitted through the pupil region 322 may be used and only the signal from the electrode 202 may be acquired.

Accordingly, even when the aperture of the image pickup optical system 11 is set to maximum aperture, an image of the pupil region 322 narrowed in the x direction in FIGS. 6A and 6B can be obtained and a picked-up image with a deeper depth of field can be acquired as compared to a case where light transmitted through the entire exit pupil 320 is used.

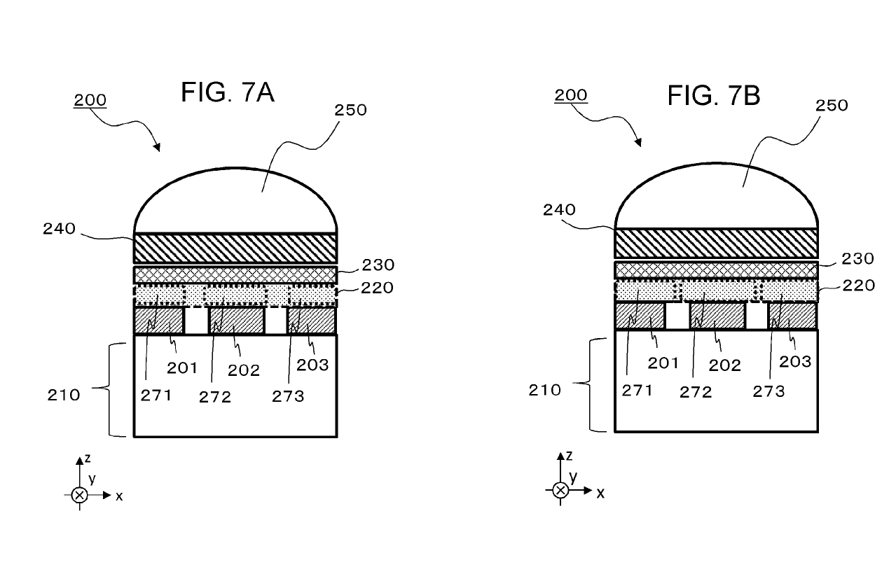

FIGS. 7A and 7B are diagrams for explaining that sizes of photoelectric conversion units 271, 272, and 273 inside the photoelectric conversion layer 220 change in accordance with a magnitude of voltage between the electrodes 201, 202, and 203 and the upper electrode 230.

FIG. 7B represents a case where the voltage has been increased as compared to FIG. 7A and, as shown in FIGS. 7A and 7B, regions of the photoelectric conversion units 271, 272, and 273 can be increased by increasing the voltage. Conversely, reducing the voltage between the electrodes 201, 202, and 203 and the upper electrode 230 enables the regions of the photoelectric conversion units 271, 272, and 273 to be reduced.

In addition, changing a magnitude of voltage respectively applied to the electrodes 201, 202, and 203 enables sizes of the photoelectric conversion units 271, 272, and 273 to be respectively changed. For example, a ratio of sizes of the photoelectric conversion units 271, 272, and 273 can be gradually changed from a center toward a periphery of the pixel region 121 to change a sensitivity region. Since light is obliquely incident to a vicinity of the periphery of the pixel region 121, boundary positions of the photoelectric conversion units 271, 272, and 273 can be changed to accommodate obliquely incident light.

In addition, the electrodes 201 and 203 may be configured to read signal charges accumulated by the photoelectric conversion units 271 and 273 and the electrode 202 may be configured to discharge signal charges accumulated by the photoelectric conversion unit 272.

Accordingly, regions of the photoelectric conversion units 271 and 273 shown in FIGS. 7A and 7B can be clearly divided and the pupil regions 321 and 323 shown in FIGS. 6A and 6B can be clearly separated from each other. As a result, ranging accuracy can be improved.

Alternatively, the electrodes 201 and 203 may be configured to discharge signal charges accumulated by the photoelectric conversion units 271 and 273 and the electrode 202 may be configured to read signal charges accumulated by the photoelectric conversion unit 272.

Accordingly, a region of the photoelectric conversion unit 272 near the center of the pixel 200 can be clearly defined and the pupil regions 322 shown in FIGS. 6A and 6B can be clearly defined. In this case, changing a magnitude of voltage applied to the electrode 202 enables the size of the photoelectric conversion units 272 to be changed and also enables the size of the pupil region 322 shown in FIGS. 6A and 6B to be changed. As a result, while keeping the aperture of the image pickup optical system 11 open, the size of the pupil region 322 can be freely changed and an effective size of the aperture can be changed.

As described above, in the present embodiment, the center of gravity position 261 of the electrode 201 and the center of gravity position 263 of the electrode 203 are displaced in the −y direction from the pixel center C in a plan view. In addition, the center of gravity position 262 of the electrode 202 is displaced in the +y direction from the pixel center C. Furthermore, shapes of the electrodes 201, 202, and 203 are respectively shapes that are not point symmetric in a plan view.

According to such a configuration, an image pickup device which suppresses image distortion due to an image pickup optical system and which has improved ranging accuracy can be provided.

In addition, since an image of the pupil region 322 narrowed in the x direction in FIGS. 6A and 6B can be obtained even when the aperture of the image pickup optical system 11 is set to maximum aperture, a picked-up image with a deeper depth of field can be acquired as compared to a case where light transmitted through the entire exit pupil 320 is used.

Furthermore, since changing a magnitude of voltage respectively applied to the electrodes 201, 202, and 203 enables sizes of the photoelectric conversion units 271, 272, and 273 to be respectively changed and a sensitivity region to be appropriately changed, an image pickup device with high sensitivity can be provided.

Moreover, by configuring the image pickup system 1 to which the image pickup device 10 is applied, a high performance image pickup system can be realized.

### Second Embodiment

Hereinafter, a second embodiment will be described.

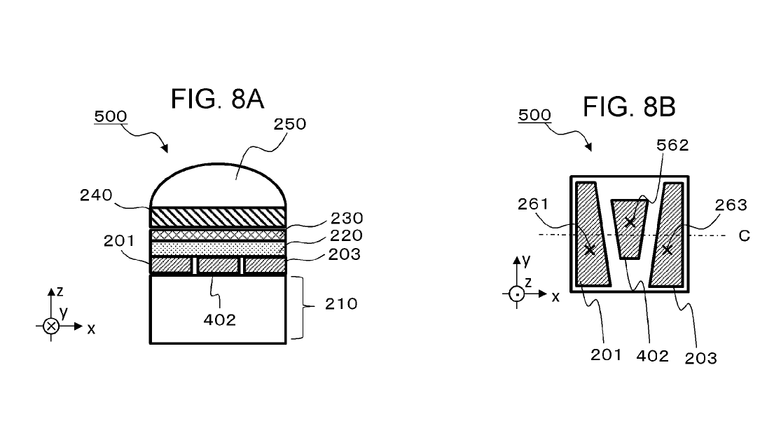

FIG. 8A is a sectional view schematically showing an xz plane of a pixel 500 according to the present embodiment. FIG. 8B is a sectional view schematically showing xy planes of electrodes 201, 402, and 203 in the pixel 500.

A configuration of the pixel 500 according to the second embodiment differs from the pixel 200 according to the first embodiment in a size of an electrode present near the center of the pixel. Specifically, as shown in FIG. 8B, the electrode 402 according to the present embodiment has a shape with a shorter length in the y direction as compared to the electrode 202 according to the first present embodiment shown in FIG. 3B. In addition, a center of gravity position 562 of the electrode 402 according to the present embodiment is displaced in the +y direction from a pixel center C. Furthermore, in a similar manner to the first embodiment, the center of gravity position 261 of the electrode 201 and the center of gravity position 263 of the electrode 203 are displaced in the −y direction from the pixel center C.

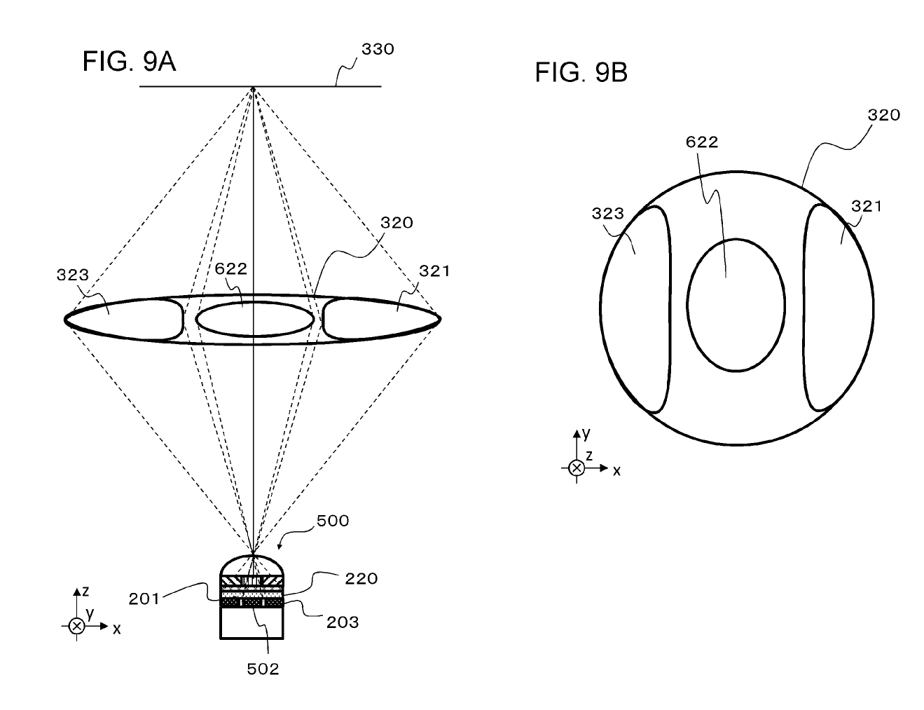

FIG. 9A is a diagram for explaining a relationship among the pixel 500, the object 330, and the exit pupil 320 according to the present embodiment in the asymmetric image pickup optical system 11 shown in FIG. 1. In FIG. 9A, the pixel 500, the exit pupil 320, and the object 330 are schematically shown arranged in one row for the sake of brevity in a similar manner to FIG. 6A according to the first embodiment.

FIG. 9B is a diagram schematically showing an xy plane of the exit pupil 320 according to the present embodiment. In the present embodiment, respective regions of the split exit pupil 320 are assumed to be pupil regions 321, 622, and 323.

Since the exit pupil 320 and the photoelectric conversion layer 220 are in a conjugate relationship, the pupil region 622 shown in FIG. 9B is shorter in the y direction as compared to the pupil region 322 shown in FIG. 6B according to the first embodiment. In the present embodiment, a pupil region through which a luminous flux used for a picked-up image passes is limited to a vicinity of an optical axis in the y direction in addition to the x direction.

Adopting such a configuration enables an image pickup device to be provided in which a depth of field does not become shallow in the x direction and the y direction even when the aperture of the image pickup optical system 11 is set to, for example, maximum aperture. Therefore, an image pickup device can be provided which is capable of suppressing image distortion due to an image pickup optical system to improve ranging accuracy and capable of acquiring a picked-up image with a deep depth of field in the x direction and the y direction.

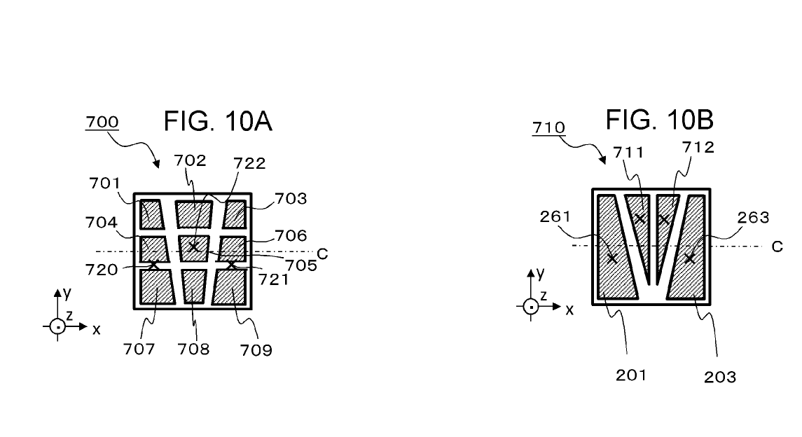

Modes in which four or more electrodes are arranged in a pixel will now be described with reference to FIGS. 10A and 10B.

FIG. 10A is a sectional view schematically showing xy planes of electrodes 701 to 709 in a pixel 700.

The electrodes shown in FIG. 10A represent a mode obtained by respectively dividing the electrodes 201, 202, and 203 shown in FIG. 3B into three parts in the y direction. Simultaneously reading signals of the electrodes 701, 704, and 707 of the pixel 700 shown in FIG. 10A corresponds to reading the signal of the electrode 201 in the pixel 500 shown in FIG. 8B. In addition, simultaneously reading signals of the electrodes 703, 706, and 709 of the pixel 700 shown in FIG. 10A corresponds to reading the signal of the electrode 203 in the pixel 500 shown in FIG. 8B. A center of gravity position of the electrodes 701, 704, and 707 is denoted by reference numeral 720, a center of gravity position of the electrodes 703, 706, and 709 is denoted by reference numeral 721, and both center of gravity positions are displaced in the −y direction from the pixel center C in a plan view.

In addition, reading a signal of the electrode 705 near the center of the pixel 700 shown in FIG. 10A corresponds to reading the signal of the electrode 402 in the pixel 500 shown in FIG. 8B. A center of gravity position 722 of the electrode 705 is displaced in the +y direction from the pixel center C in a plan view.

Even with the pixel 700 shown in FIG. 10A, an image pickup device which is capable of suppressing image distortion due to an image pickup optical system and achieving both high ranging accuracy and picked-up images with a deep depth of field in the x direction and the y direction can be provided in a similar manner to the pixel 500 shown in FIGS. 8A and 8B.

In addition, by configuring the pixel 700 as shown in FIG. 10A, since electrodes are also divided and arranged in the y direction, ranging can be performed not only in the x direction but also in the y direction. Furthermore, signals to be read from the electrodes 701 to 709 can be freely selected and ranging can also be performed in a diagonal direction with respect to the xy plane.

A mode in which four or more electrodes are arranged in a pixel is not limited to the mode shown in FIG. 10A.

FIG. 10B is a sectional view schematically showing xy planes of electrodes 201, 711, 712, and 203 in a pixel 710.

FIG. 10B represents a mode obtained by dividing the electrode 202 present near the center of the pixel among the electrodes 201, 202, and 203 shown in FIG. 3B into two electrodes 711 and 712 in the x direction.

According to such a mode, the pupil region 322 shown in FIGS. 6A and 6B or the pupil region 622 shown in FIGS. 9A and 9B can also be divided into two parts in the x direction. In this case, simultaneously reading a signal of the electrode 201 and a signal of the electrode 711 and simultaneously reading a signal of the electrode 203 and a signal of the electrode 712 enables the exit pupil 320 to be divided into left and right halves and signals to be obtained from the respective halves. Accordingly, a degree of freedom of a range in which ranging is to be performed can be increased.

### Third Embodiment

Hereinafter, a third embodiment will be described.

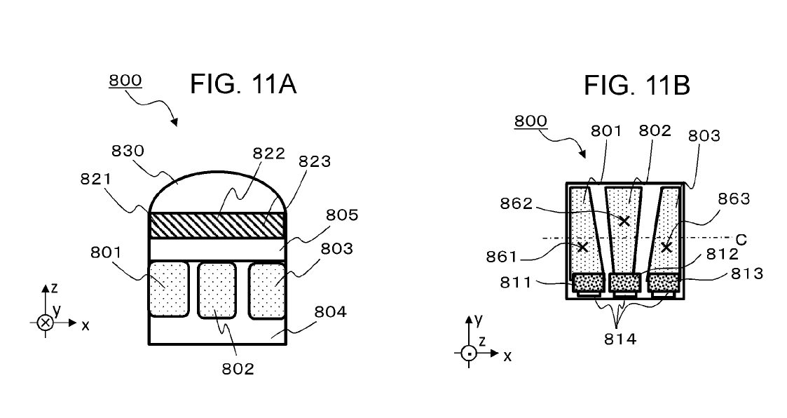

FIG. 11A is a sectional view schematically showing an xz plane of a pixel 800 according to the present embodiment. FIG. 11B is a sectional view schematically showing xy planes of photoelectric conversion units 801, 802, and 803 in the pixel 800.

In the first and second embodiments described above, photoelectric conversion units are constituted by the lower electrode (the electrodes 201, 202, and 203), the upper electrode 230, and the photoelectric conversion layer 220 sandwiched between the lower electrode and the upper electrode 230.

In contrast, the photoelectric conversion units 801, 802, and 803 according to the present embodiment are formed by introducing an impurity to a semiconductor substrate 804.

An insulating film 805, a color filter 821, and a microlens 830 are arranged on the semiconductor substrate 804. In addition, as shown in FIG. 11B, gate electrodes 811, 812, and 813 of a transfer transistor are arranged so as to respectively correspond to the photoelectric conversion units 801, 802, and 803. The gate electrodes 811, 812, and 813 of the transfer transistor transfer charges generated in the photoelectric conversion units 801, 802, and 803 to a floating diffusion region 814.

Shapes of the photoelectric conversion units 801, 802, and 803 shown in FIG. 11B are asymmetric shapes in a plan view. In addition, a center of gravity position 861 of the photoelectric conversion unit 801 and a center of gravity position 863 of the photoelectric conversion unit 803 are displaced in the −y direction from a pixel center C in a plan view. A center of gravity position 862 of the photoelectric conversion unit 802 is displaced in the +y direction from the pixel center C in a plan view.

Adopting the pixel 800 according to the present embodiment enables an image pickup device which suppresses image distortion due to an image pickup optical system and which has improved ranging accuracy to be provided in a similar manner to the first embodiment.

While the present embodiment describes a case of a so-called back-illuminated pixel 800, a front-illuminated pixel with a wiring layer arranged inside the insulating film 805 may be adopted instead.

### Fourth Embodiment

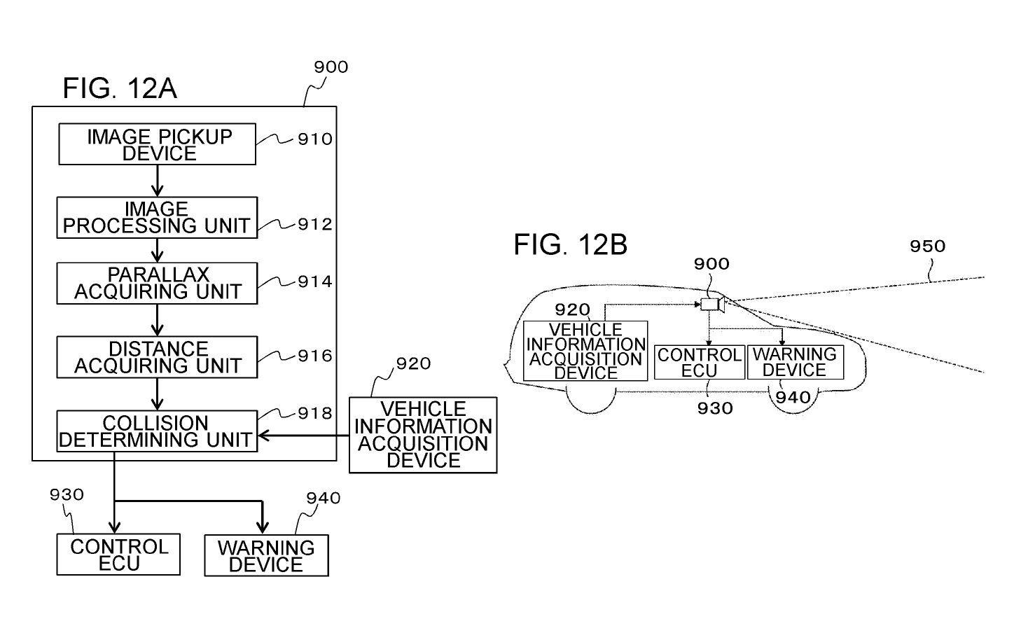

An image pickup system and a moving apparatus according to a fourth embodiment will be described below with reference to FIGS. 12A and 12B. FIGS. 12A and 12B are diagrams showing configurations of the image pickup system and the moving apparatus according to the present embodiment.

FIG. 12A shows an example of an image pickup system 900 related to a vehicle-mounted camera. The image pickup system 900 has an image pickup device 910. The image pickup device 910 is any of the image pickup devices 10 described in the first to third embodiments. The image pickup system 900 has an image processing unit 912 which performs image processing on a plurality of pieces of image data acquired by the image pickup device 910 and a parallax acquiring unit 914 which calculates a parallax (for example, a phase difference of a parallax image) from the plurality of pieces of image data acquired by the image pickup device 910. In addition, the image pickup system 900 has a distance acquiring unit 916 which calculates a distance to an object based on the calculated parallax and a collision determining unit 918 which determines whether or not there is a possibility of a collision based on the calculated distance. In this case, the parallax acquiring unit 914 and the distance acquiring unit 916 are examples of a distance information acquiring unit which acquires information related to a distance to the object. In other words, distance information is information related to a parallax, a defocus amount, a distance to the object, or the like. The collision determining unit 918 may determine a possibility of a collision using any of these pieces of distance information. The distance information acquiring unit may be realized by exclusively-designed hardware or may be realized by a software module. In addition, the distance information acquiring unit may be realized by an FPGA (Field Programmable Gate Array), an ASIC (Application

Specific Integrated Circuit), or the like or by a combination thereof.

The image pickup system 900 is connected to a vehicle information acquisition device 920 and is capable of acquiring vehicle information such as a vehicle speed, a yaw rate, and a steering angle. In addition, a control ECU 930 which is a control device that outputs a control signal causing a vehicle to generate a braking force based on a determination result of the collision determining unit 918 is connected to the image pickup system 900. In other words, the control ECU 930 is an example of a moving apparatus control unit which controls a moving apparatus based on distance information. Furthermore, the image pickup system 900 is also connected to a warning device 940 which issues a warning to a driver based on a determination result of the collision determining unit 918. For example, when it is found that the possibility of a collision is high as a determination result of the collision determining unit 918, the control ECU 930 performs vehicle control involving applying the brakes, releasing the gas pedal, suppressing engine output, or the like to avoid a collision and/or reduce damage. The warning device 940 issues a warning to a user by sounding an alarm, displaying warning information on a screen of a car navigation system or the like, vibrating a seat belt or a steering wheel, or the like.

In the present embodiment, an image of a periphery of the vehicle such as the front or the rear of the vehicle is picked up by the image pickup system 900. FIG. 12B shows the image pickup system 900 in a case where an image of the front of the vehicle (an image pickup range 950) is picked up. The vehicle information acquisition device 920 sends an instruction to operate the image pickup system 900 and have the image pickup system 900 perform image pickup. Using the image pickup devices 10 according to the first to third embodiments described above as the image pickup device 910 enables the image pickup system 900 according to the present embodiment to improve accuracy of ranging.

While an example of controlling a vehicle to prevent a collision with another vehicle has been described above, the image pickup system can also be applied to controlling automated driving so that the vehicle follows another vehicle, controlling automated driving so that the vehicle stays within a lane, and the like. In addition, the image pickup system is not limited to a vehicle such as an automobile and can also be applied to a moving apparatus (moving body) such as a ship, an airplane, or an industrial robot. Furthermore, besides moving bodies, the image pickup system can be applied to a wide variety of devices that utilize object recognition such as an intelligent transportation system (ITS).

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-8967, filed on Jan. 23, 2018, which is hereby incorporated by reference herein in its entirety.

What is claimed is:

1. An image pickup device in which a plurality of pixels are two-dimensionally arranged on a substrate, wherein
at least one of the plurality of pixels includes:
a first photoelectric conversion unit and a second photoelectric conversion unit arranged side by side in a first direction; and
a third photoelectric conversion unit arranged between the first photoelectric conversion unit and the second photoelectric conversion unit in the first direction, and
the first photoelectric conversion unit, the second photoelectric conversion unit, and the third photoelectric conversion unit respectively have shapes that are not point symmetric in a plan view.

2. An image pickup device in which a plurality of pixels are two-dimensionally arranged on a substrate, wherein
at least one of the plurality of pixels includes:
a first photoelectric conversion unit and a second photoelectric conversion unit arranged side by side in a first direction; and
a third photoelectric conversion unit arranged between the first photoelectric conversion unit and the second photoelectric conversion unit in the first direction, and
a position of a center of gravity of the first photoelectric conversion unit and a position of a center of gravity of the second photoelectric conversion unit are displaced toward a same side from a center of the pixel in a second direction that is perpendicular to the first direction in a plane parallel to a surface of the substrate, and
a position of a center of gravity of the third photoelectric conversion unit is displaced toward an opposite side to the position of the center of gravity of the first photoelectric conversion unit and the position of the center of gravity of the second photoelectric conversion from the center of the pixel in the second direction.

3. The image pickup device according to claim 1, wherein the pixel has
at least three pixel electrodes,
a photoelectric conversion layer provided on the three pixel electrodes, and
a counter electrode provided on the photoelectric conversion layer,
the first photoelectric conversion unit is constituted by a first pixel electrode, the photoelectric conversion layer, and the counter electrode,
the second photoelectric conversion unit is constituted by a second pixel electrode, the photoelectric conversion layer, and the counter electrode, and
the third photoelectric conversion unit is constituted by a third pixel electrode, the photoelectric conversion layer, and the counter electrode.

4. The image pickup device according to claim 3, wherein
the first pixel electrode, the second pixel electrode, and the third pixel electrode have shapes that differ from one another in a plan view.

5. The image pickup device according to claim 3, wherein
at least any of the first pixel electrode, the second pixel electrode, and the third pixel electrode is constituted by a plurality of electrodes arranged in a second direction that is perpendicular to the first direction in a plane parallel to a surface of the substrate.

6. The image pickup device according to claim 3, wherein
the third pixel electrode is constituted by a plurality of electrodes arranged in the first direction.

7. The image pickup device according to claim 3, wherein
a charge generated in the first photoelectric conversion unit is read by the first pixel electrode,
a charge generated in the second photoelectric conversion unit is read by the second pixel electrode, and
a charge generated in the third photoelectric conversion unit is discharged by the third pixel electrode.

8. The image pickup device according to claim 3, wherein
a charge generated in the first photoelectric conversion unit is discharged by the first pixel electrode,
a charge generated in the second photoelectric conversion unit is discharged by the second pixel electrode, and
a charge generated in the third photoelectric conversion unit is read by the third pixel electrode.

9. The image pickup device according to claim 1, wherein
the first photoelectric conversion unit, the second photoelectric conversion, and the third photoelectric conversion unit are formed inside the substrate.

10. The image pickup device according to claim 1, wherein
a plurality of microlenses are arranged so as to correspond to a plurality of pixels.

11. The image pickup device according to claim 1, wherein
the first photoelectric conversion unit and the second photoelectric conversion unit are arranged side by side in the first direction for detecting a phase difference.

12. The image pickup device according to claim 2, wherein
the first photoelectric conversion unit and the second photoelectric conversion unit are arranged side by side in the first direction for detecting a phase difference.

13. An image pickup system, comprising:
the image pickup device according to claim 1; and
a signal processing unit which processes signals output from the image pickup device.

14. A moving apparatus, comprising:
the image pickup device according to claim 1;
a distance information acquiring unit which acquires information on a distance to an object based on a signal output from the pixel of the image pickup device; and
a control unit which controls the moving apparatus based on the distance information.
